(19) United States
(12) Patent Application Publication
(10) Pub. No.: US 2017/0248782 A1
(43) Pub. Date: Aug. 31, 2017

(54) LASER IRRADIATION DEVICE

(71) Applicant: Gigaphoton Inc., Tochigi (JP)

(72) Inventors: Kouji KAKIZAKI, Oyama-shi (JP); Akira SUWA, Oyama-shi (JP); Osamu WAKABAYASHI, Oyama-shi (JP)

(73) Assignee: Gigaphoton Inc., Tochigi (JP)

(21) Appl. No.: 15/594,849

(22) Filed: May 15, 2017

Related U.S. Application Data
(63) Continuation of application No. PCT/JP2014/083183, filed on Dec. 15, 2014.

(51) Int. Cl. G02B 26/10; H01L 21/02; H01L 27/12; G21K 5/08; G21K 5/10

(52) U.S. Cl. CPC G02B 26/10; G21K 5/08; G21K 5/10; H01L 27/1285; H01L 21/02532; H01L 21/02592; H01L 21/02686; G21K 2201/067

(57) ABSTRACT

A laser irradiation device may include: a laser device configured to emit a pulse laser beam; beam scan optics configured to allocate the pulse laser beam emitted from the laser device to optical paths; beam homogenizers provided in the respective optical paths, each of the beam homogenizers being configured to homogenize distribution of light intensity of the pulse laser beam allocated to a corresponding optical path of the optical paths; and a controller configured to control the beam scan optics to allocate, for each pulse, the pulse laser beam emitted from the laser device to the corresponding optical path of the optical paths.

### TECHNICAL FIELD

The present disclosure relates to a laser irradiation device.

### BACKGROUND ART

A laser annealing apparatus may apply a pulse laser beam on an amorphous silicon film formed on a glass substrate. The pulse laser beam may be emitted from a laser system such as an excimer laser system. The pulse laser beam may have a wavelength of ultraviolet light region. Such pulse laser beam may reform the amorphous silicon film to a poly-silicon film. The poly-silicon film can be used to form thin film transistors (TFTs). The TFTs may be used in large sized liquid crystal displays.

Patent Document 1: Japanese Patent Application Publication No. 2014-139991 A

Patent Document 2: Japanese Patent Application Publication No. 2012-243818 A

Patent Document 3: Japanese Patent Application Publication No. 2011-233597 A

Patent Document 4: Japanese Patent Application Publication No. 2005-099427 A

Patent Document 5: International Publication No. WO 2011/132385 A

### SUMMARY

A laser irradiation device according to an aspect of the present disclosure may include: a laser device configured to emit a pulse laser beam; beam scan optics configured to allocate the pulse laser beam emitted from the laser device to optical paths; beam homogenizers provided in the respective optical paths, each of the beam homogenizers being configured to homogenize distribution of light intensity of the pulse laser beam allocated to a corresponding optical path of the optical paths; and a controller configured to control the beam scan optics to allocate, for each pulse, the pulse laser beam emitted from the laser device to the corresponding optical path of the optical paths.

A laser irradiation method according to an aspect of the present disclosure may include: generating a pulse laser beam; moving a stage in a first direction; and changing an optical path of the pulse laser beam to cause the pulse laser beam to enter beam homogenizers in turn, the beam homogenizers being arranged in a second direction.

### BRIEF DESCRIPTION OF DRAWINGS

Exemplary embodiments of the present disclosure will be described below with reference to the appended drawings.

FIG. 1A schematically shows a configuration of a laser irradiation device according to a comparative example.

FIG. 1B schematically shows the configuration of the laser irradiation device according to the comparative example.

FIG. 1C is a plan view of a workpiece S irradiated with a pulse laser beam by the laser irradiation device shown in FIGS. lA and 1B.

FIG. 2A schematically shows a configuration of a laser irradiation device according to a first embodiment of the present disclosure.

FIG. 2B schematically shows the configuration of the laser irradiation device according to the first embodiment of the present disclosure.

FIG. 2C is a plan view of a workpiece S irradiated with a pulse laser beam by the laser irradiation device shown in FIGS. 2A and 2B.

FIG. 2D is a timing chart of a laser emission trigger and the pulse laser beam in the laser irradiation device shown in FIGS. 2A and 2B.

FIG. 3A schematically shows a configuration of a laser irradiation device according to a second embodiment of the present disclosure.

FIG. 3B schematically shows the configuration of the laser irradiation device according to the second embodiment of the present disclosure.

FIG. 3C is a plan view of a workpiece S irradiated with a pulse laser beam by the laser irradiation device shown in FIGS. 3A and 3B and a mask 6 included in the laser irradiation device.

FIG. 3D is a plan view of the mask 6 included in the laser irradiation device shown in FIGS. 3A and 3B.

FIG. 4A shows a first modification of the mask and the irradiation regions according to the second embodiment.

FIG. 4B shows the first modification of the mask according to the second embodiment.

FIG. 5A shows a second modification of the mask and the irradiation regions according to the second embodiment.

FIG. 5B shows the second modification of the mask according to the second embodiment.

FIG. 6A schematically shows a configuration of a laser irradiation device according to a third embodiment of the present disclosure.

FIG. 6B schematically shows the configuration of the laser irradiation device according to the third embodiment of the present disclosure.

FIG. 7A schematically shows a configuration of a laser irradiation device according to a fourth embodiment of the present disclosure.

FIG. 7B schematically shows the configuration of the laser irradiation device according to the fourth embodiment of the present disclosure.

FIG. 7C is a plan view of a workpiece S irradiated with a laser beam by the laser irradiation device shown in FIGS. 7A and 7B and a mask 6 included in the laser irradiation device.

FIG. 7D is a plan view of the mask 6 included in the laser irradiation device shown in FIGS. 7A and 7B.

FIG. 8A shows a modification of the mask and the irradiation regions in the fourth embodiment.

FIG. 8B shows the modification of the mask in the Fourth embodiment.

FIG. 9 schematically shows a configuration of a laser irradiation device according to a fifth embodiment of the present disclosure.

FIG. 10 schematically shows a configuration of an ultraviolet laser device 2 used in each of the above-described embodiments.

FIGS. 11A to 11C schematically show a configuration of a fly-eye lens 501 used in each of the above-described embodiments.

FIG. 12 is a block diagram schematically illustrating a configuration of a controller.

### DESCRIPTION OF EMBODIMENTS

<Contents>
Outline
2. Laser Irradiation Device According to Comparative Example
   2.1 Configuration
   2.2 Operation
   2.3 Problems
3. Laser Irradiation Device Including Beam Scan Optics (First Embodiment)
   3.1 Configuration
   3.2 Operation
   3.3 Effects
   3.4 Others
4. Laser Irradiation Device Including Micro-Lens Array (Second Embodiment)
   4.1 Configuration
   4.2 Operation
   4.3 Effects
   4.4 Others
5. Laser Irradiation Device Where Beam Homogenizer and Transfer Optics are Integrated with Each Other (Third Embodiment)
   6. Laser Irradiation Device with Mask Having Rectangular Openings (Fourth Embodiment)
   6.1 Configuration
   6.2 Effects
   6.3 Others
7. Laser Irradiation Device Using Galvanometer Mirror (Fifth Embodiment)
8. Others
   8.1 Ultraviolet Laser Device
   8.2 Fly-Eye Lens
   8.3 Configuration of Controller

Embodiments of the present disclosure will be described in detail below with reference to the drawings. The embodiments described below may represent several examples of the present disclosure, and may not intend to limit the content of the present disclosure. Not all of the configurations and operations described in the embodiments are indispensable in the present disclosure. Identical reference symbols may be assigned to identical elements and redundant descriptions may be omitted.

### 1. Outline

A laser irradiation device used in a laser annealing apparatus may scan an amorphous silicon film with a pulse laser beam. A scanning operation may be performed such that TFT regions of the amorphous silicon film are each irradiated with the pulse laser beam. The TFT regions may be arranged in two or more lines on the amorphous silicon film. This may suppress throughput in irradiating each of the TFT regions with the pulse laser beam. In addition, it may be difficult to efficiently scan a large substrate with the pulse laser beam.

In one aspect of the present disclosure, the laser irradiation device may include beam scan optics and beam homogenizers. The beam scan optics may allocate the pulse laser beam to two or more optical paths. The beam homogenizers may be provided in the respective optical paths. Each of the beam homogenizers may homogenize distribution of light intensity of the pulse laser beam that has been branched to each optical path.

### 2. Laser Irradiation Device According to Comparative Example

2.1 Configuration

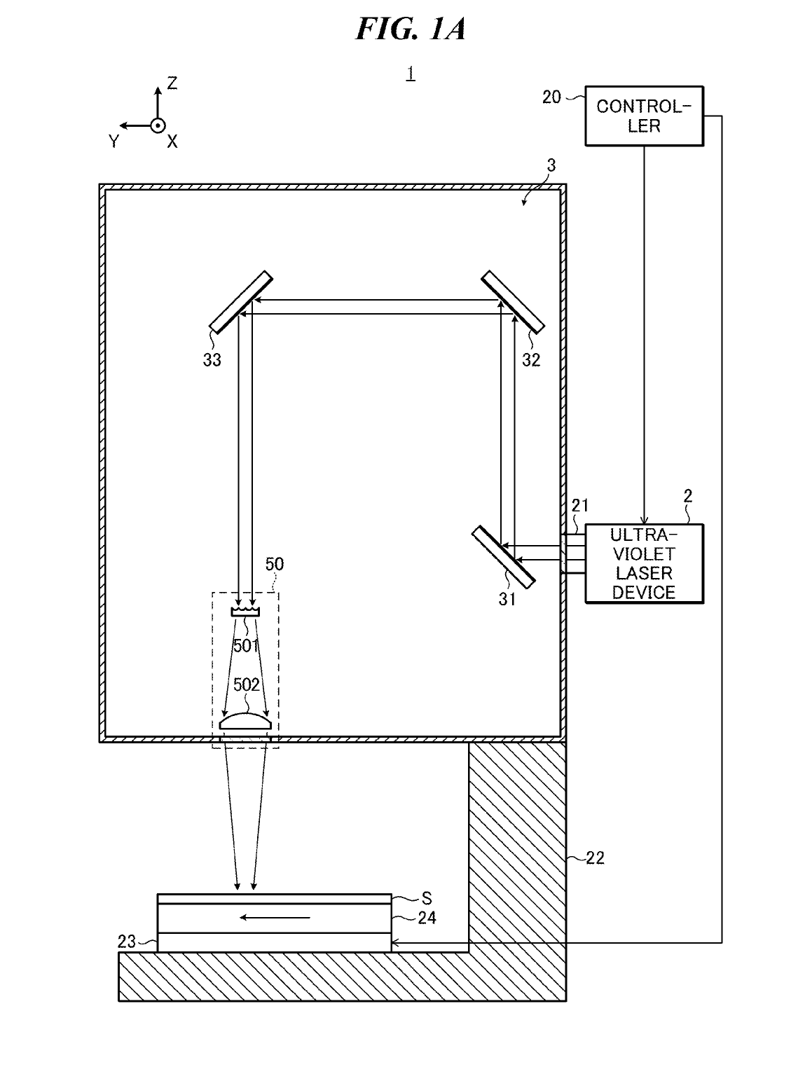

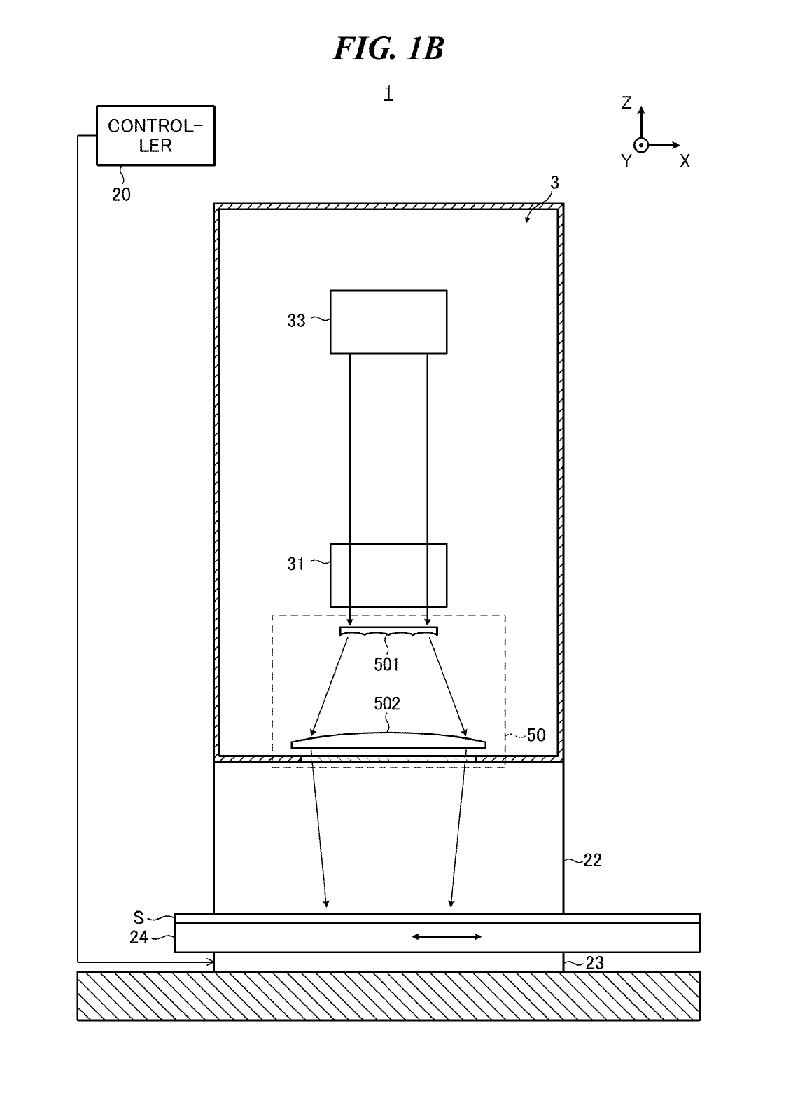

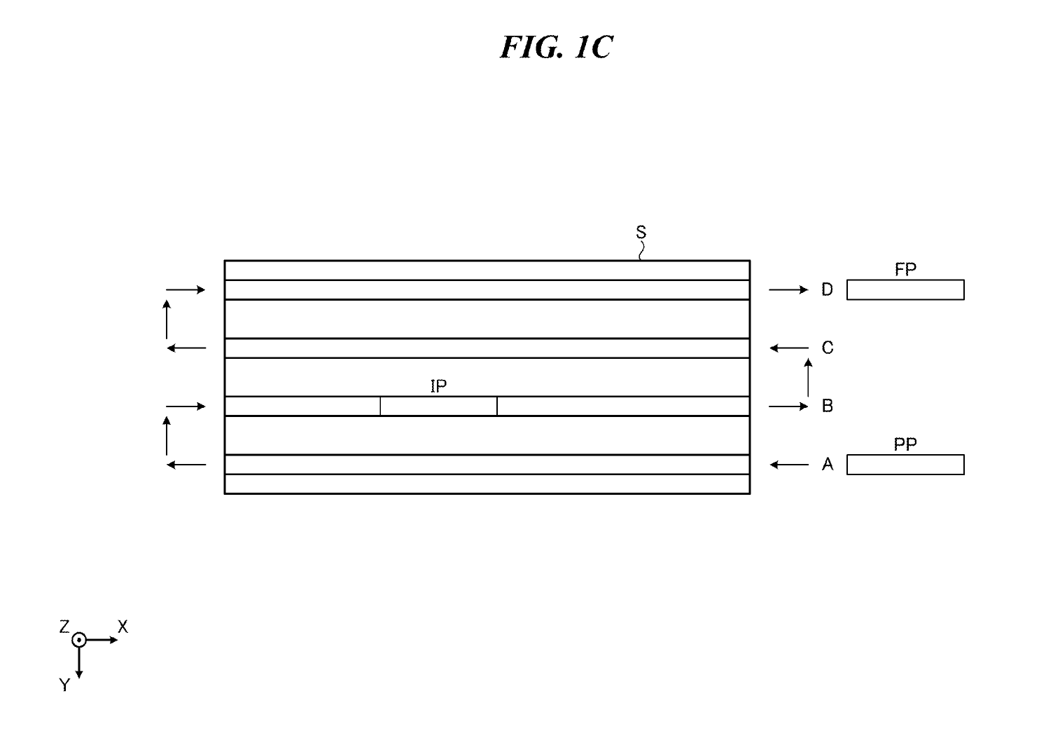

FIGS. 1A and 1B schematically show a configuration of a laser irradiation device according to a comparative example. A laser irradiation device 1 may include an ultraviolet laser device 2, a controller 20, a beam path tube 21, a frame 22, an XYZ stage 23, a table 24, and an optical system 3.

The ultraviolet laser device 2 may be capable of emitting a pulse laser beam of ultraviolet light that may anneal, for example, amorphous silicon. The ultraviolet laser device 2 may be, for example, a discharge excited excimer laser device that uses any one of ArF, KrF, XeCl, and XeF as a laser medium. A traveling direction of the pulse laser beam traveling from the ultraviolet laser device 2 to the optical system 3 may be a Y direction. The pulse laser beam may be a flat-shaped pulse laser beam having a cross-sectional shape longer in an X direction than in a Z direction. In the following description, the X direction and the Y direction may be directions along an irradiation surface of a workpiece S irradiated with the pulse laser beam. The Z direction may be a direction opposite to a traveling direction of the pulse laser beam being incident on the workpiece S. The X direction, the Y direction, and the Z direction may be perpendicular to one another.

Here, the workpiece S may be, for example, a glass substrate provided with an amorphous silicon film.

The optical system 3 may include a plurality of high-reflective mirrors 31, 32, and 33, and a beam homogenizer 50. The high-reflective mirrors 31, 32, and 33 may be configured to guide the pulse laser beam that has been emitted from the ultraviolet laser device 2, to the beam homogenizer 50. The beam homogenizer 50 may include a fly-eye lens 501 and condenser optics 502, and may be designed to configure Koehler illumination that homogenizes the distribution of the light intensity of the pulse laser beam. The fly-eye lens 501 may include multiple lenses that are arranged in a cross-section of the beam. The cross-section of the beam may be perpendicular to an optical path axis of the pulse laser beam that has been reflected by the high-reflective mirrors 31, 32, and 33. Each of the multiple lenses may allow a corresponding portion of the pulse laser beam to pass therethrough toward the condenser optics 502, expanding a beam width of the corresponding portion of the pulse laser beam.

The condenser optics 502 may be disposed such that a front-side focal plane of the condenser optics 502 is substantially coincident with a focal position of each lens of the fly-eye lens 501, and a rear-side focal plane of the condenser optics 502 is substantially coincident with a surface of the workpiece S. The condenser optics 502 may allow the pulse laser beam that has been emitted from the fly-eye lens 501 to pass therethrough, reducing the beam width of the pulse laser beam.

The above-described configuration may cause the beam homogenizer 50 to reduce variation in the distribution of the light intensity on the cross-section of the pulse laser beam being incident on the workpiece S. The traveling direction of the pulse laser beam that is emitted from the beam homogenizer 50 and then enters the workpiece S may be a direction. The pulse laser beam may be a flat-shaped pulse laser beam having a cross-sectional shape longer in the X direction than in the Y direction.

The controller 20 may be configured to send a control signal to the ultraviolet laser device 2 and the XYZ stage 23. The table 24 may hold the workpiece S. The XYZ stage 23 may be capable of moving the table 24 in the X direction, the Y direction, and the Z direction.

The frame 22 may house the above-described optical system 3. In addition, the frame 22 may hold the XYZ stage 23 and the table 24 mentioned above. The beam path tube 21 may be connected between the ultraviolet laser device 2 and the frame 22.

2.2 Operation

FIG. 1C is a plan view of the workpiece S irradiated with the pulse laser beam by the laser irradiation device shown in FIGS. 1A and 1B. The controller 20 included in the laser irradiation device 1 may control the XYZ stage 23 such that the pulse laser beam emitted from the beam homogenizer 50 is applied to an initial position PP on an extension of a line A in the workpiece S shown in FIG. 1C.

The controller 20 may send a laser emission trigger in a predetermined repetition frequency, to the ultraviolet laser device 2. As a result, a pulse laser beam may be emitted from the ultraviolet laser device 2, then be reflected by the high-reflective mirrors 31, 32, and 33, and then enter the beam homogenizer 50. The pulse laser beam may be applied to the initial position PP.

The controller 20 may control the XYZ stage 23 to move the table 24 at a predetermined velocity in the X direction. This may move an irradiation region irradiated with the pulse laser beam in a −X direction along the line A.

After irradiation of the pulse laser beam along the line A is completed, the controller 20 may control the XYZ stage 23 to move the table 24 by a predetermined distance in the Y direction. This may move the irradiation region irradiated with the pulse laser beam to a position on an extension of a line B in the workpiece S shown in FIG. 1C.

The controller 20 may control the XYZ stage 23 to move the table 24 at a constant velocity in the −X direction. This may move an irradiation region IP irradiated with the pulse laser beam in the X direction along the line B.

Likewise, the irradiation region irradiated with the pulse laser beam may be moved in the −X direction along a line C in the workpiece S shown in FIG. 1C. Further, the irradiation region irradiated with the pulse laser beam may be moved in the X direction along a line D in the workpiece S shown in. FIG. 1C. When the irradiation region irradiated with the pulse laser beam is moved to a final position FP on an extension of the line D, the controller 20 may stop emission of the pulse laser beam. Reciprocating the table 24 in the X direction and in the −X direction, while moving the table 24 in the Y direction in such a manner, may cause the pulse laser beam to be applied to the lines on which the TFT regions are arranged.

2.3 Problems

In the method of reciprocating the table 24 in the X and −X directions while moving the table 24 in the Y direction as mentioned above, it may be necessary that the XYZ stage 23 sequentially switches the moving direction, while positioning the table 24 on each of the extensions of the lines. Such scanning operation of the pulse laser beam may take a long time, which may suppress the throughput. In addition, it may be difficult to efficiently scan a large substrate with the pulse laser beam.

In embodiments described below to solve the problems, beam scan optics may be added to allow the stage to move only in one direction.

### 3. Laser Irradiation Device Including Beam Scan Optics (First Embodiment)

3.1 Configuration

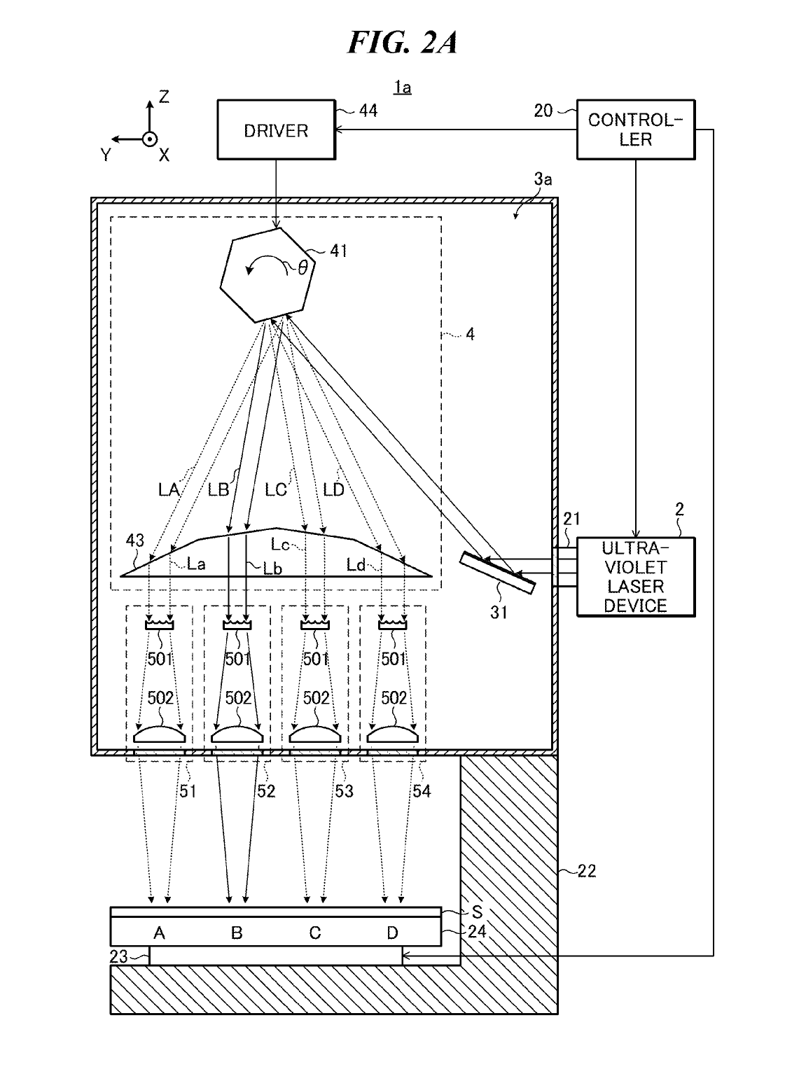

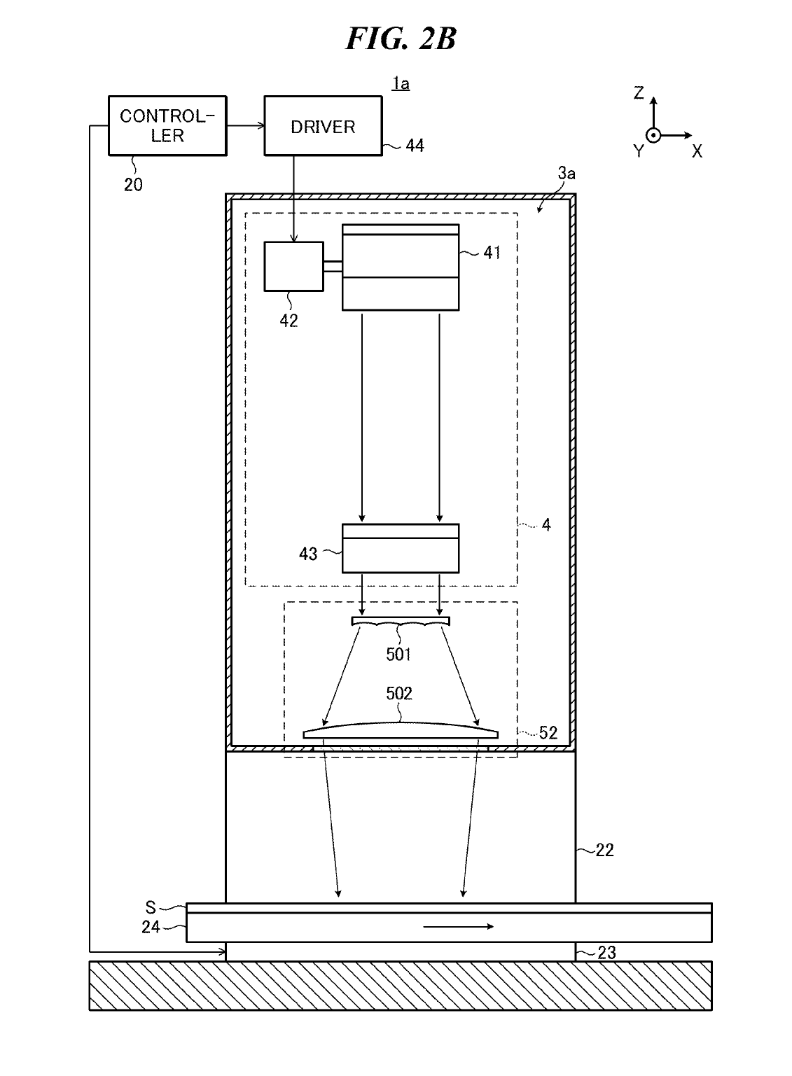

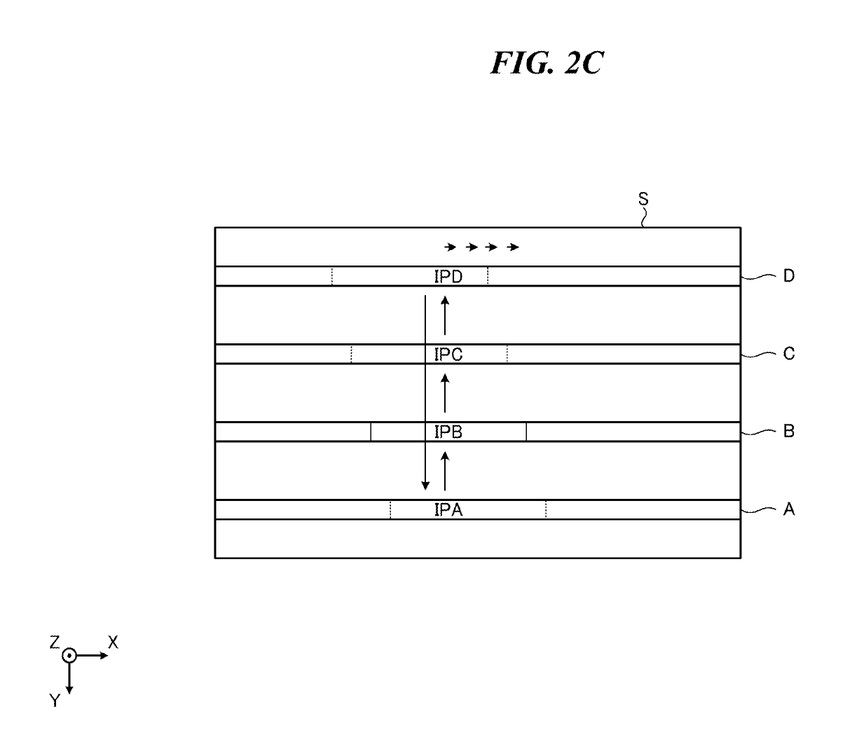

FIGS. 2A and 2B each schematically show a configuration of a laser irradiation device according to a first embodiment of the present disclosure. In a laser irradiation device la according to the first embodiment, an optical system 3a may include beam scan optics 4, in addition to the components of the optical system described with reference to FIGS. 1A and 1B. In addition, in the laser irradiation device 1a according to the first embodiment, the optical system 3a may include beam homogenizers 51 to 54.

The beam scan optics 4 may include a polygon mirror 41, a motor 42, and a prism 43. The polygon mirror 41 may have, for example, a regular hexagonal prism shape, and may be provided in the optical path of the pulse laser beam that has been reflected by the high-reflective mirror 31. Each of six side surfaces of the polygon mirror 41 may be coated with a film that reflects the pulse laser beam with high reflectivity. The pulse laser beam may be incident on one of the six side surfaces of the polygon mirror 41.

The polygon mirror 41 may be connected to a rotation shaft of the motor 42. A driver 44 may drive the motor 42, which may rotate the rotation shaft of the motor 42. The controller 20 may control the driver 44 to rotate the rotation shaft of the motor 42 at a predetermined rotational frequency.

The polygon mirror 41 may be rotated by the motor 42 in one direction at the predetermined rotational frequency to change an incident angle of the pulse laser beam on the one of the side surfaces of the polygon mirror 41.

Change in the incident angle of the pulse laser beam on the one of the side surfaces of the polygon mirror 41 may cause the optical path of the pulse laser beam reflected by the polygon mirror 41 to be changed. For example, the polygon mirror 41 may be rotated in a direction indicated by an arrow θ in FIG. 2A to change the optical path of the pulse laser beam reflected by the polygon mirror 41. The optical path may be changed for each pulse in the following order: an optical path LA; an optical path LB; an optical path LC; and an optical path LD.

The polygon mirror 41 may be further rotated by the motor 42 to switch the side surfaces of the polygon mirror 41 on which the pulse laser beam is incident. If a pulse travels along the optical path LD, then the next pulse may travel along the optical path LA.

The prism 43 may have a pentagonal prism shape. The prism 43 may be made of a material that allows the pulse laser beam to pass therethrough at high transmittance. A surface of the prism 43 through which the pulse laser beam passes may be coated with an anti-reflection film. Pulses of the pulse laser beam that have been reflected by the polygon mirror 41 to travel along the respective optical paths LA to LD may each be refracted by the prism 43 to travel in the −Z direction.

The beam scan optics 4 may thus allocate the pulse laser beam reflected by the high-reflective mirror 31 to first to fourth optical paths La to Ld in turn.

The beam homogenizers 51 to 54 may be provided in the first to fourth optical paths La to Ld, respectively, of the pulse laser beam allocated by the beam scan optics 4. Each of the beam homogenizers 51 to 54 may have a configuration substantially the same as the configuration of the beam homogenizer 50 described with reference to FIGS. 1A and 1B.

3.2 Operation

FIG. 2C is a plan view of the workpiece S irradiated with the pulse laser beam by the laser irradiation device shown in FIGS. 2A and 2B. FIG. 2D is a timing chart of the laser emission trigger and the pulse laser beam in the laser irradiation device shown. in FIGS. 2A and 2B.

The controller 20 may control the XYZ stage 23 to cause the respective pulse laser beams emitted from the beam homogenizers 51 to 54 to be incident on the respective extensions of the lines A to D in the workpiece S shown in FIG. 2C. The controller 20 may send the laser emission trigger in the predetermined repetition frequency f to the ultraviolet laser device 2. The predetermined repetition frequency f may be, for example, 4 kHz.

The controller 20 may control the driver 44 to rotate the rotation shaft of the motor 42 at the predetermined rotational frequency. The predetermined rotational frequency may be represented by f/(6×4), for example, when the polygon mirror 41 has the regular hexagonal prism shape and the four lines A to D are irradiated with the respective pulses.

A first pulse included in the pulse laser beam that has been emitted from the ultraviolet laser device 2 may be reflected by the polygon mirror 41 in a direction along the optical path LA, and the first pulse may then be changed in the traveling direction by the prism 43 to the −Z direction. The first pulse may pass through the beam homogenizer 51 and be incident on an irradiation region IPA on the line A.

A second pulse that has been emitted next to the first pulse from the ultraviolet laser device 2 may be reflected by the polygon mirror 41 in the direction along the optical path LB, and the second pulse may then be changed in the traveling direction by the prism 43 to the −Z direction. The second pulse may pass through the beam homogenizer 52 and be incident on an irradiation region IPB on the line B.

A third pulse that has been emitted next to the second pulse from the ultraviolet laser device 2 may be reflected by the polygon mirror 41 in the direction along the optical path LC, and the third pulse may then be changed in the traveling direction by the prism 43 to the −Z direction. The third pulse may pass through the beam homogenizer 53 and be incident on an irradiation region IPC on the line C.

A fourth pulse that has been emitted. next to the third pulse from the ultraviolet laser device 2 may be reflected by the polygon mirror 41 in the direction along the optical path LD, and the fourth pulse may then be changed in the traveling direction by the prism 43 to the −Z direction. The fourth pulse may pass through the beam homogenizer 54 and be incident on an irradiation region IPD on the line D.

A fifth pulse that has been emitted next to the fourth pulse from the ultraviolet laser device 2 may be reflected by the polygon mirror 41 in the direction along the optical path LA, and the fifth pulse may then be changed in the traveling direction by the prism 43 to the −Z direction. The fifth pulse may pass through the beam homogenizer 51 and be incident on the line A. The irradiation region irradiated with the fifth pulse may be shifted in the −X direction from the irradiation region IPA irradiated with the first pulse.

The beam scan optics 4 may be controlled in the above-described manner such that the pulse laser beam is incident on the lines A to D in turn. As a result, the pulse laser beam may be applied at a repetition frequency of f/4 in each of the lines A to D.

The controller 20 may control the XYZ stage 23 to move the workpiece S in the X direction at a constant velocity while controlling the beam scan optics 4. When the irradiation region in the workpiece S irradiated with the pulse laser beam reaches a final position in the −X direction in the workpiece S, the controller 20 may stop emission of the pulse laser beam.

Other configurations may be substantially the same as those of the laser irradiation device described with reference to FIGS. 1A to 1C.

3.3 Effects

According to the first embodiment, the pulses included in the pulse laser beam may be allocated to the lines by the beam scan optics 4 in the above-described configuration and operation. Further, moving the workpiece S in the X direction only once may allow the pulse laser beam to be applied to each of the lines. This may improve efficiency in the scanning operation with the pulse laser beam.

Moreover, the pulse laser beam to be applied to the workpiece S is shaped to the flat-shaped pulse laser beam according to each shape of the lines in which the TFTs are formed. Thus, energy density of the pulse laser beam may be higher than that in a case where the pulse laser beam is applied to an entire surface of the workpiece S.

Furthermore , the pulse laser beam t say be applied to the plurality of lines while the workpiece S is moved in the X direction. Thus, using a laser device with high repetition frequency may cause low repetition frequency of the pulse laser beam applied to each of the lines. As a result, pulse laser beam with high repetition frequency may be applied to the lines according to the moving velocity of the stage.

3.4 Others

In the first embodiment, the pulse laser beam is allocated by the beam scan optics 4 to the four beam homogenizers 51 to 54; however, the present disclosure is not limited thereto. It may be sufficient to allocate the pulse laser beam to two or more beam homogenizers.

In the first embodiment, the pulse laser beam is refracted by the prism 43 to travel in the −Z direction; however, the present disclosure is not limited thereto. The pulse laser beam may be changed in the traveling direction by a high-reflective mirror (not shown) to travel in the −Z, direction to enter the beam homogenizers.

### 4. Laser Irradiation Device Including Micro-Lens Array (Second Embodiment)

4.1 Configuration

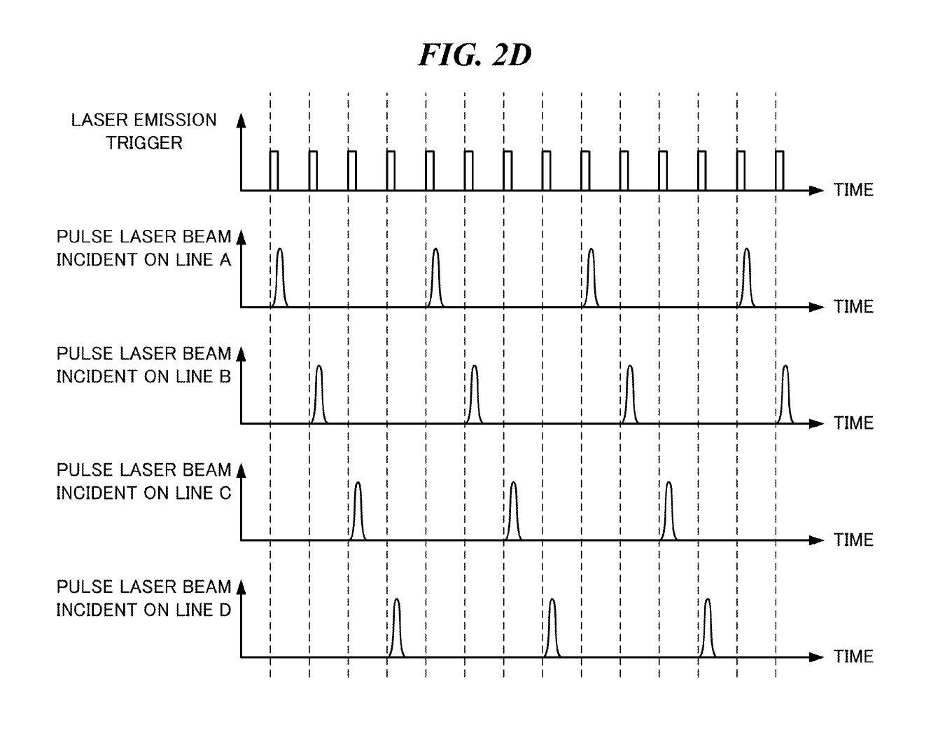

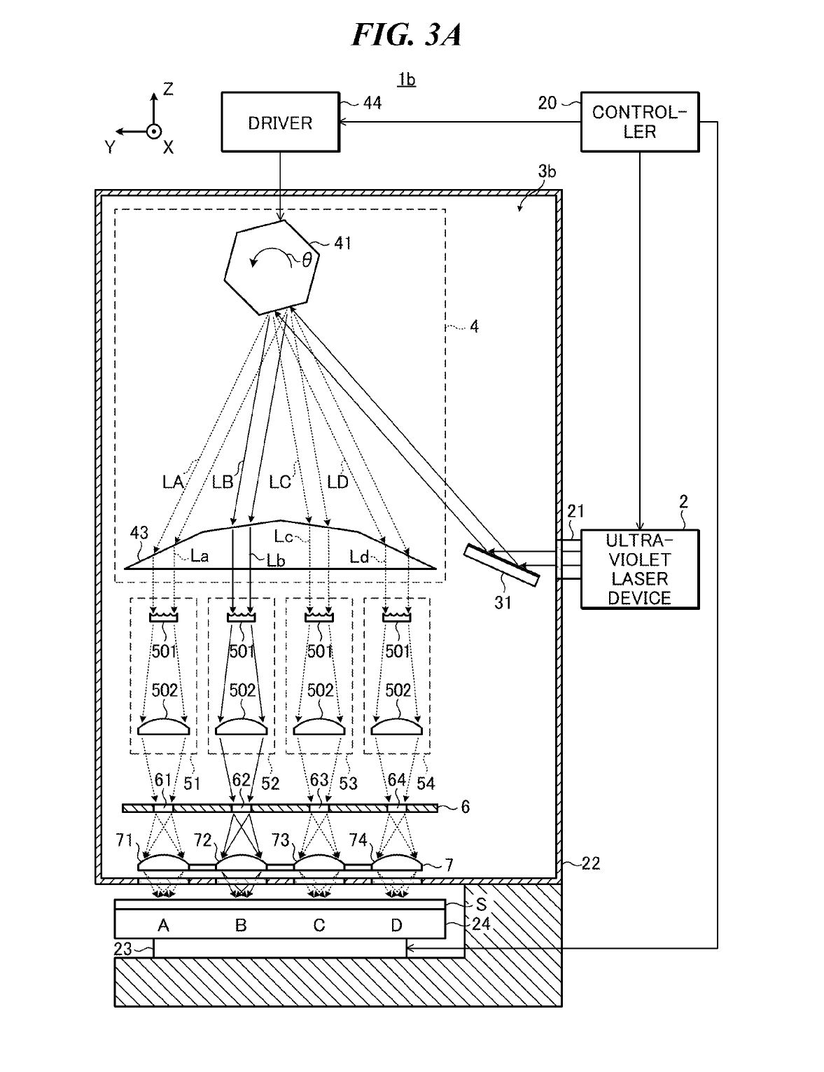

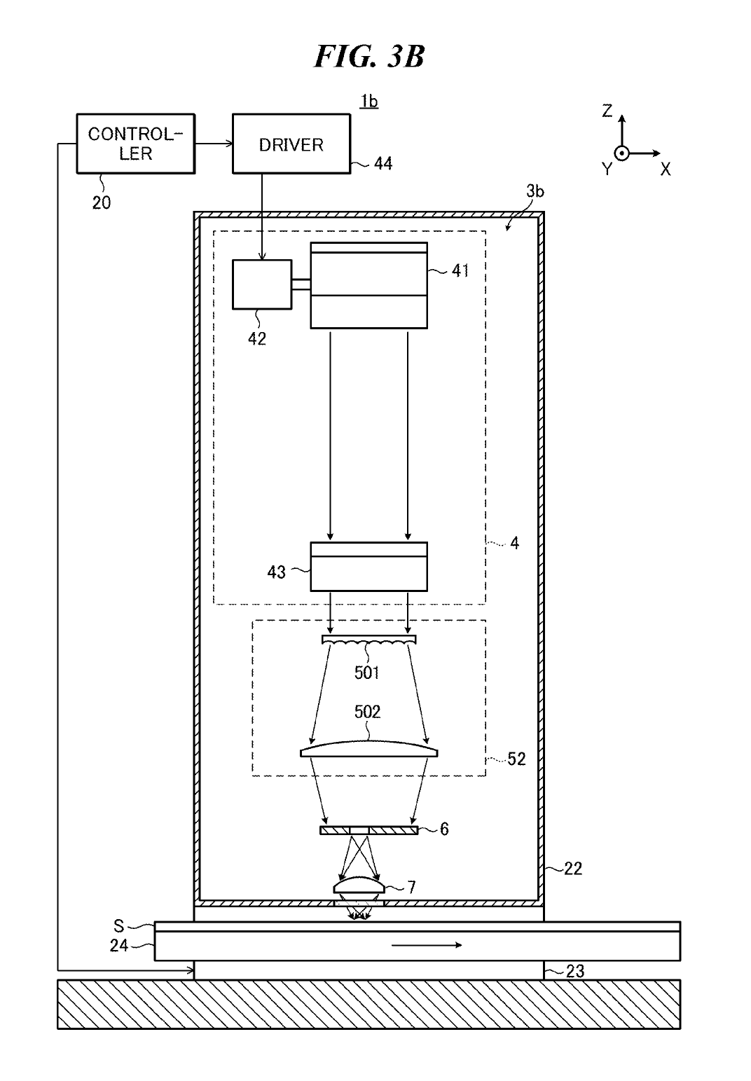

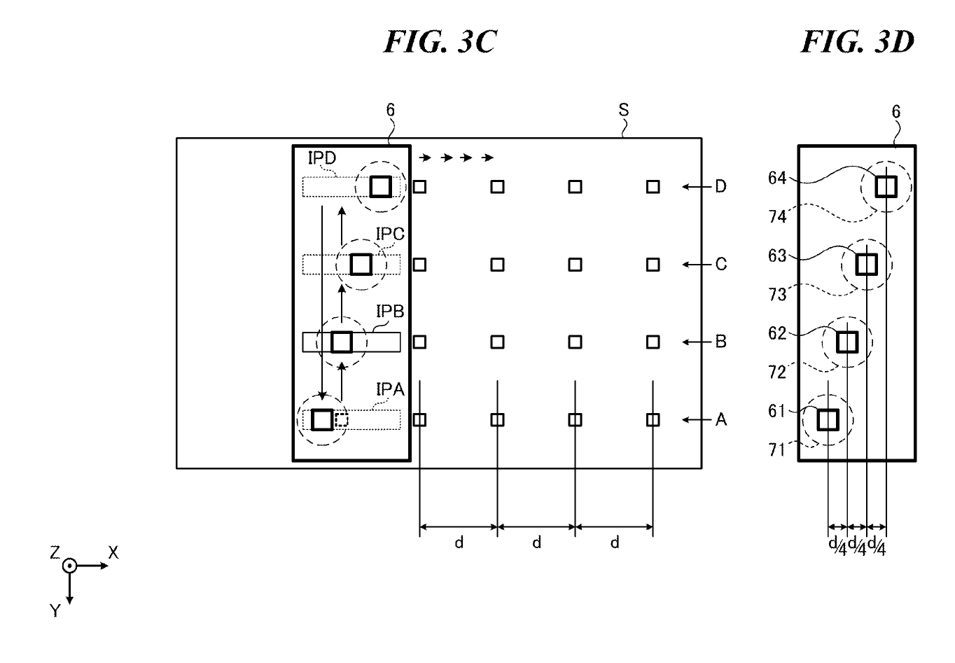

FIGS. 3A and 3B schematically show a configuration of a laser irradiation device according to a second embodiment of the present disclosure. In a laser irradiation device lb according to the second embodiment, an optical systemsystem 3b may include a mask 6 and a micro-lens array 7, in addition to the optical system described with reference to FIGS. 2A to 2C.

The condenser optics 502 included in each of the beam homogenizers 51 to 54 may be disposed such that the mask 6 is substantially coincident with the rear-side focal plane of the condenser optics 502.

FIG. 3C is a plan view of the workpiece S irradiated with the pulse laser beam by the laser irradiation device shown in FIGS. 3A and 3B, and the mask 6 included in the laser irradiation device. FIG. 3D is a plan view of the mask 6 included in the laser irradiation device shown in FIGS. 3A and 3B. The mask 6 may have a plurality of openings 61 to 64 each having a shape that corresponds to a shape of a TFT region of the workpiece S. The opening 61 may correspond to the TFT region on the line A, the opening 62 may correspond to the TFT region on the line B, the opening 63 may correspond to the TFT region on the line C, and the opening 64 may correspond to the TFT region on the line D. When an interval between the TFT regions in the X direction is denoted by d in each of the lines A to D, the respective positions of the openings 61 to 64 provided in the mask 6 may be shifted by a distance d/4 from one another in the X direction.

The micro-lens array 7 may include lenses 71 to 74. The lenses 71 to 74 may be disposed at respective positions that are overlapped with the respective openings 61 to 64 provided in the mask 6, as viewed from the Z direction. Therefore, when the interval between the TFT regions in the X direction is denoted by d, the positions of the lenses 71 to 74 in the X direction may be shifted by the distance d/4 from one another. The lenses 71 to 74 may be configured to transfer respective images of the openings 61 to 64 to the surface of the workpiece S. A transfer magnification may be preferably one or lower.

4.2 Operation

The controller 20 may send the laser emission trigger in the predetermined repetition frequency f to the ultraviolet laser device 2. The mask 6 may be irradiated with the flat-shaped pulse laser beam that has a cross-sectional shape longer in the X direction than in the Y direction. The controller 20 may control the beam scan optics 4 such that the pulse laser beam is applied to the irradiation regions IPA to IPD in turn that are respectively overlapped with the openings 61 to 64 of the mask 6.

The controller 20 may control the XYZ stage 23 to move the workpiece S in the X direction at a constant velocity v. Here, when the four lines A to D are irradiated with the pulse laser beam, the velocity v may be expressed by the following formula.

v=(f/4)·d

Accordingly, the workpiece S may be moved in the X direction by the distance d/4 in every one pulse of the pulse laser beam. Namely, the workpiece S may be moved in the X direction by the distance d in every four pulses of the pulse laser beam.

Therefore, the images of the respective openings 61 to 64 of the mask 6 transferred to the workpiece S by the micro-lens array 7 may be shifted by the distance d in the X direction from one another. The pulse laser beam may thus be applied in a lattice shape.

Other configurations may be substantially the same as those described with reference to FIGS. 2A to 2D.

4.3 Effects

According to the second embodiment, the images of the openings 61 to 64 of the mask 6 are transferred to the surface of the workpiece S at a magnification equal to or lower than one by the above-described configuration and operation. Utilization efficiency of the pulse laser beam may thus be improved.

In addition, a plurality of lines may be irradiated with the pulse laser beam while moving the workpiece S in the X direction only once. This may allow the scanning operation with the pulse laser beam to be efficiently performed.

In addition, the pulse laser beam may be applied to the plurality of lines while the workpiece S is moved in the X direction. Thus, using a laser device with high repetition frequency may cause low repetition frequency of the pulse laser beam applied to each of the lines.

Further, in the present embodiment, the pulse laser beam may be applied to the TFT regions arranged in a lattice shape. As a result, utilization efficiency of the pulse laser beam may be improved.

4.4 Others

In the second embodiment, the pulse laser beam is allocated to the four beam homogenizers 51 to 54 by the beam scan optics 4; however, the present disclosure is not limited thereto. An integer of two or more may be denoted by J, and the pulse laser beam may be allocated to J beam homogenizers. In this case, the positions of the respective openings of the mask may be shifted by a distance d/J from one another in the X direction. The velocity v of the XYZ stage 23 in the X direction may be expressed by the following formula.

v=(f/J)·d

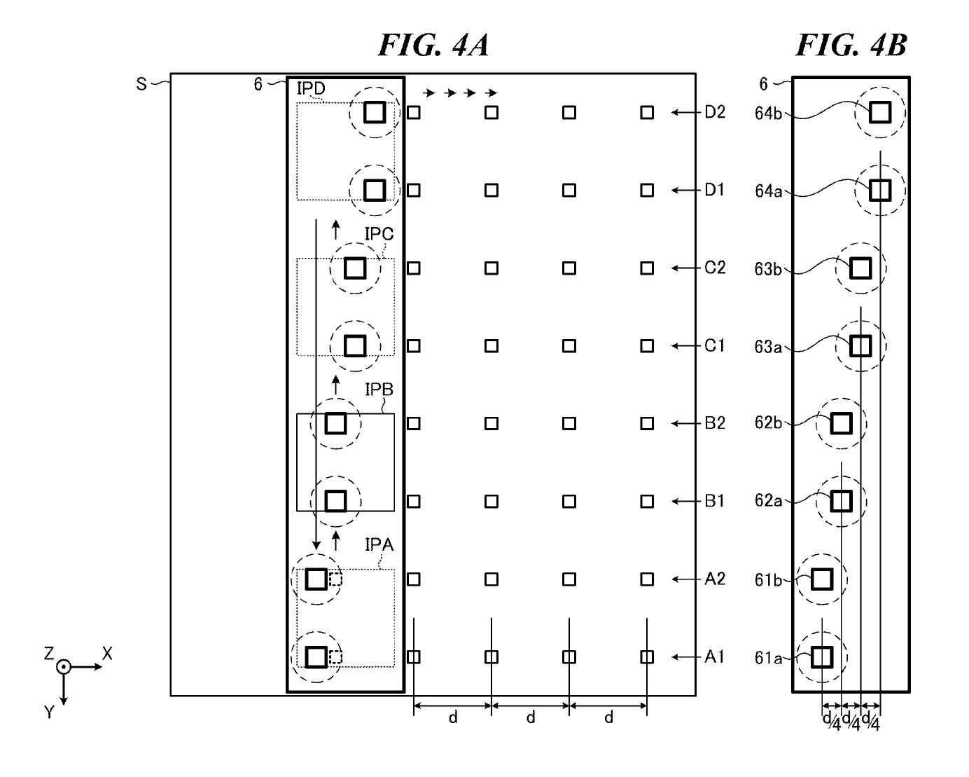

FIG. 4A shows a first modification of the mask and the irradiation regions according to the second embodiment. FIG. 4B shows the first modification of the mask according to the second embodiment. As shown in FIG. 4A, the TFT regions in the workpiece S may be disposed on eight lines A1, A2, B1, B2, C1, C2, D1, and D2. In addition, an irradiation region irradiated with a single pulse of the pulse laser beam may extend over two lines adjacent to each other. In the mask 6 shown in FIGS. 4A and 4B, positions of openings 61a and 61b corresponding to the irradiation region IPA irradiated with the first pulse may not necessarily be shifted from each other in the X direction. Neither positions of openings 62a and 62b, nor positions of openings 63a and 63b , nor positions of openings 64a and 64b may necessarily be shifted from each other in the X direction. In the mask 6 shown in FIGS. 4A and 4B, positions of the openings corresponding to separate irradiation regions irradiated with the different pulses may be shifted by the distance d/4 from one another in the X direction.

According to the present modification, the pulse laser beam may be applied to a desired position even if intervals of the lines are smaller than the intervals of the beam homogenizers. &p In FIGS. 4A and 4B, an irradiation region irradiated with a single pulse extends over the two lines adjacent to each other; however, the present disclosure is not limited thereto.

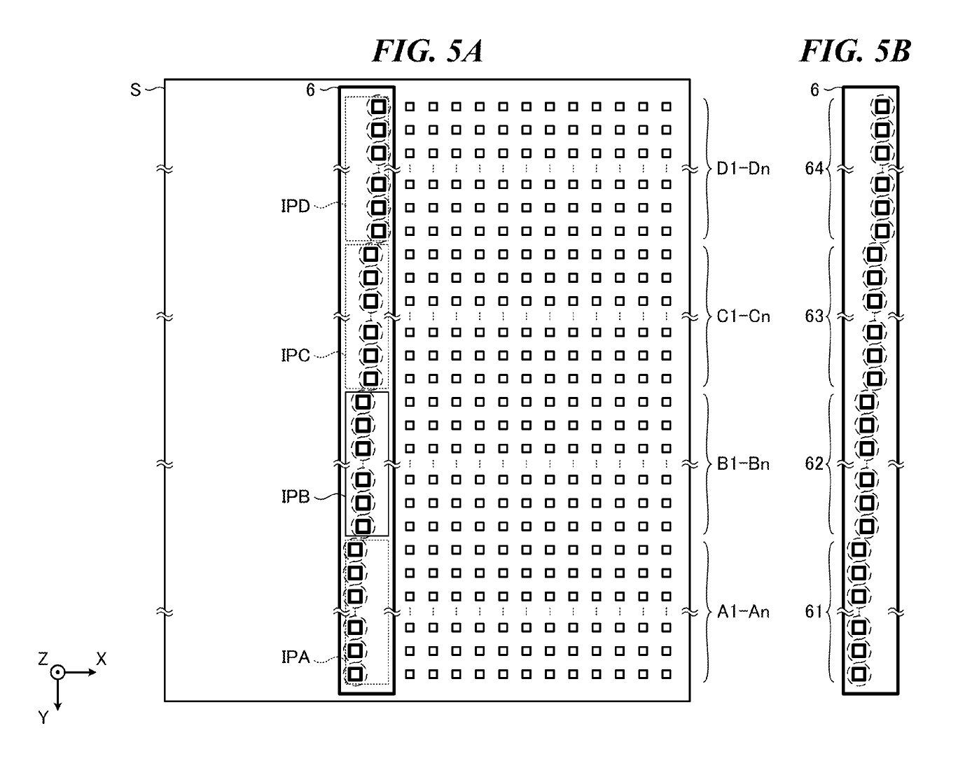

FIG. 5A shows a second modification of the mask and the irradiation regions according to the second embodiment. FIG. 5B shows the second modification of the mask according to the second embodiment. As shown in FIGS. 5A and 5B, an irradiation region irradiated with a single pulse may extend over three or more lines.

With the irradiation region irradiated with the single pulse extending over three or more lines, the pulse laser beam may be applied on the workpiece S in a lattice shape even if the intervals between the lines are small (for example, about 500 gm).

### 5. Laser Irradiation Device Where Beam Homogenizer and Transfer Optics are Integrated with Each Other (Third Embodiment)

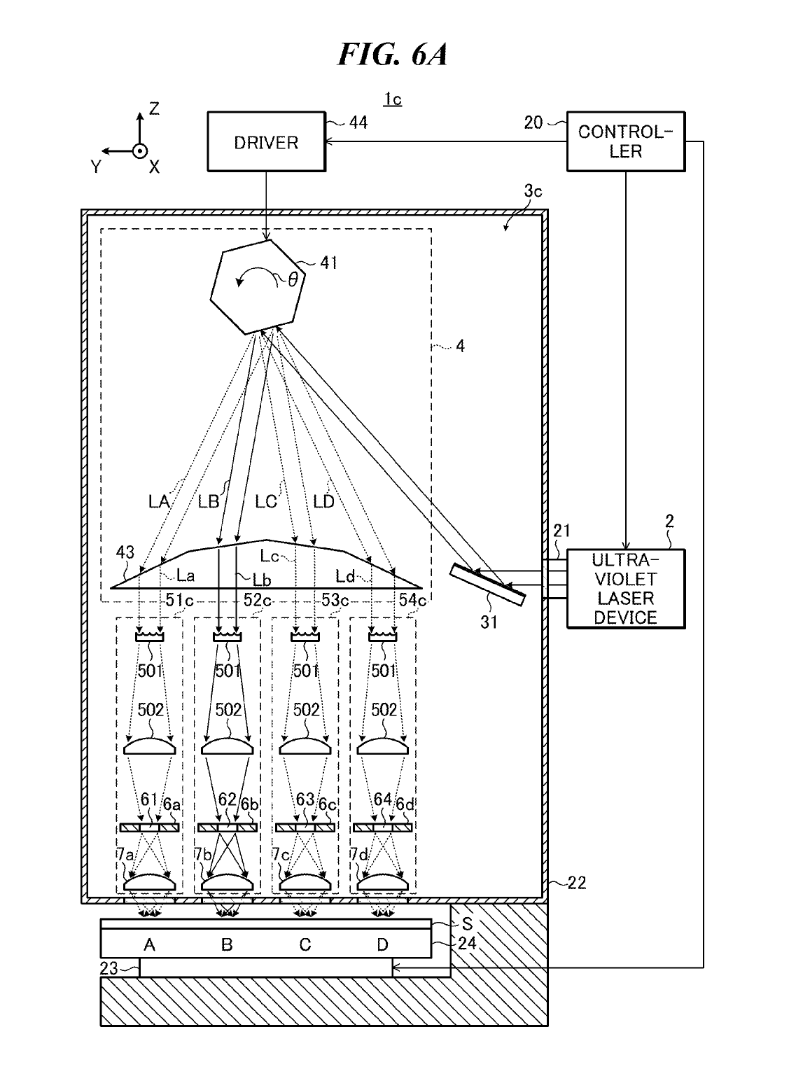

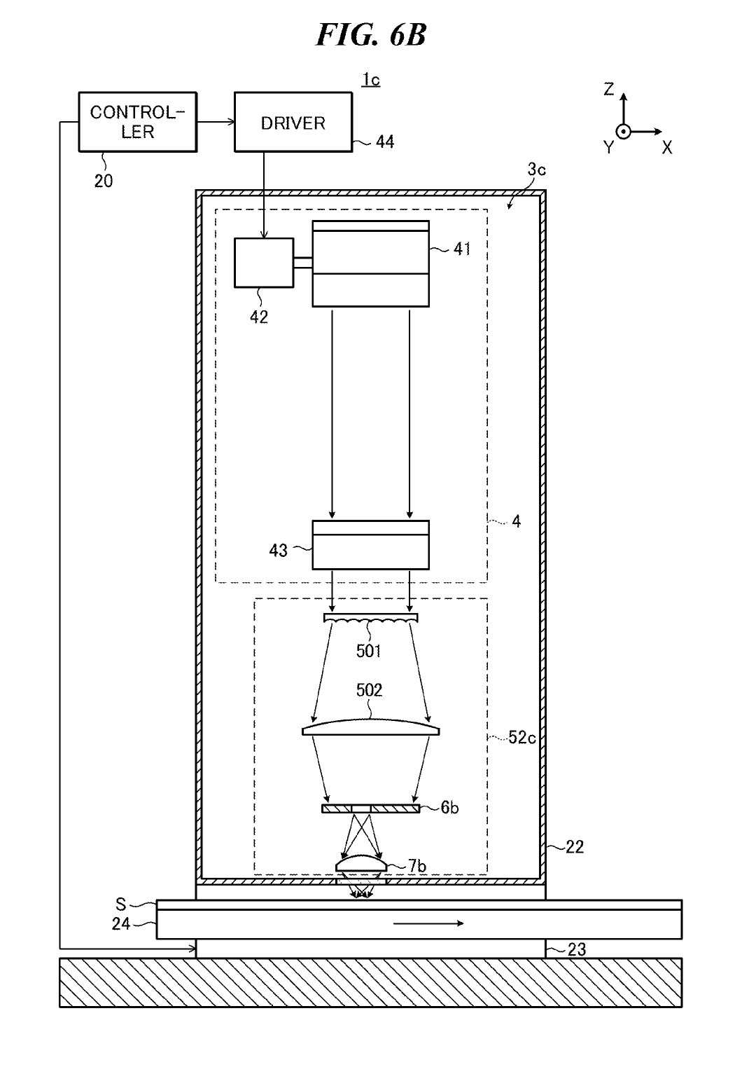

FIGS. 6A and 6B schematically show a configuration of a laser irradiation device according to a third embodiment of the present disclosure. In a laser irradiation device lc in the third embodiment, the mask and the micro-lens array may each be divided into pieces corresponding to be homogenizers Sic to 54c. Masks 6a to 6d may have openings 61 to 64, respectively. Lenses 7a to 7d may be provided at positions shifted from the openings 61 to 64, respectively, in the −Z direction. The masks 6a to 6d may be included in the beam homogenizers 51c to 54c, respectively. The lenses 7a to 7d may be included in the beam homogenizers 51c to 54c, respectively.

Other configurations may be substantially the same as those described with reference to FIGS. 3A to 3D, 4A, 43, 5A, and 5B.

### 6. Laser Irradiation Device with Mask Having Rectangular Openings (Fourth Embodiment)

6.1 Configuration

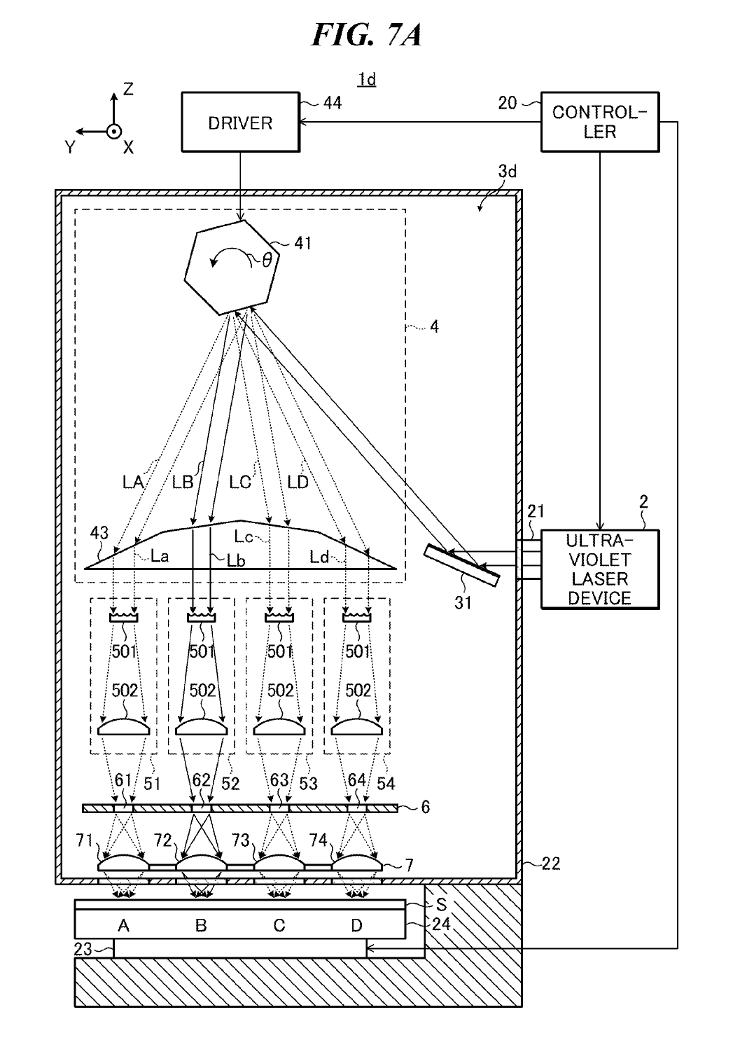

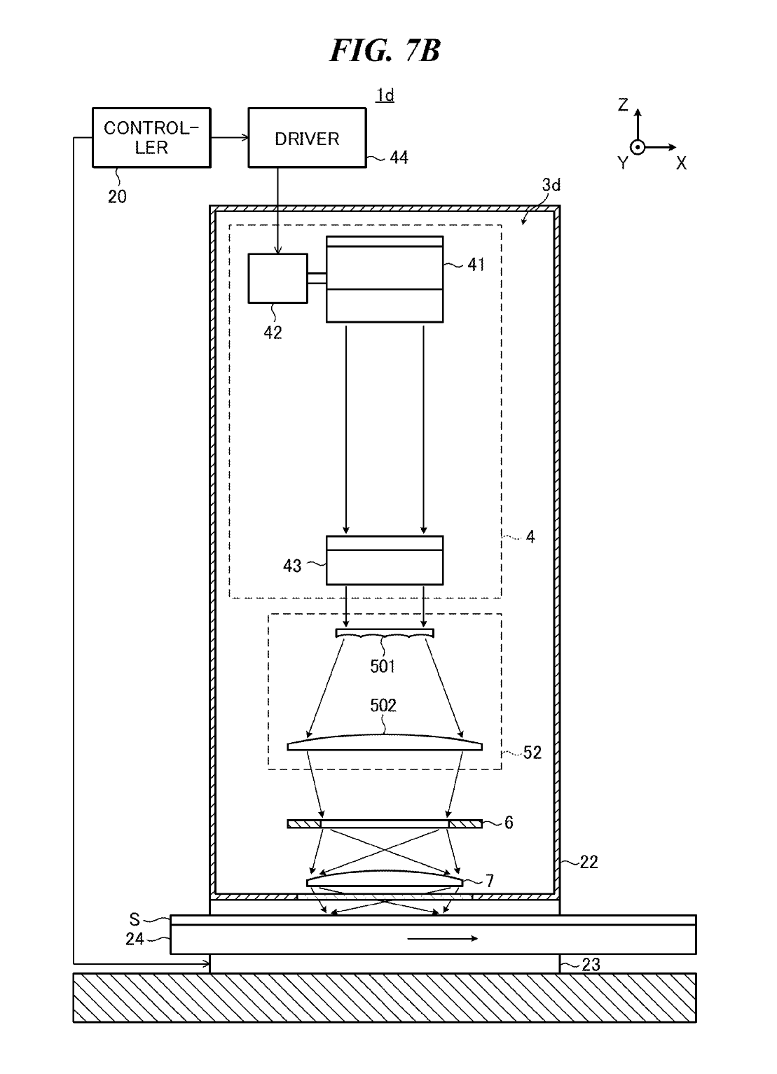

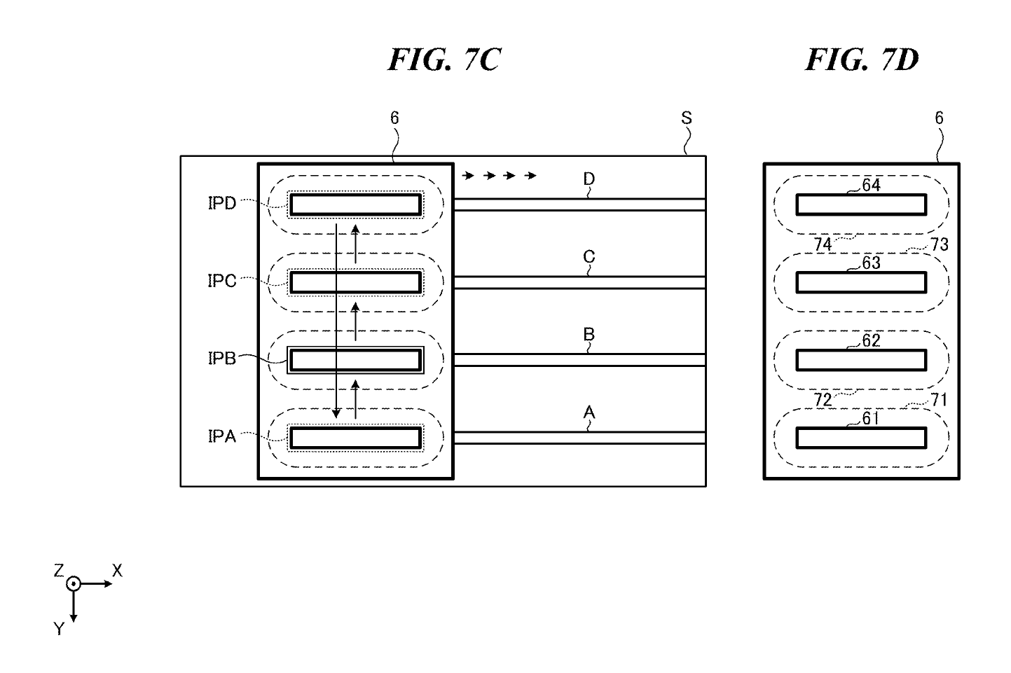

FIGS. 7A and 7B schematically show a configuration of a laser irradiation device according to a fourth embodiment of the present disclosure. FIG. 7C is a plan view of the workpiece S irradiated with the pulse laser beam by the laser irradiation device shown in FIGS. 7A and 7B, and the mask 6 included in the laser irradiation device. FIG. 7D is a plan view of the mask 6 included in the laser irradiation device shown in FIGS. 7A and 7B. In a laser irradiation device ld in the fourth embodiment, the openings 61 to 64 provided in the mask 6 and the lenses 71 to 74 included in the micro-lens array 7 may each have a shape longer in the X direction than in the Y direction.

The lenses 71 to 74 may transfer the images of the rectangular openings 61 to 64, respectively, to the workpiece S.

Other configurations may be substantially the same as those described with reference to FIGS. 2A to 2D.

6.2 Effects

The lenses 71 to 74 may transfer the images of the rectangular openings 61 to 64, respectively, to the workpiece S. This may improve uniformity of distribution of light intensity of the laser beam near an edge of each of the irradiation regions, as compared with the first embodiment.

6.3 Others

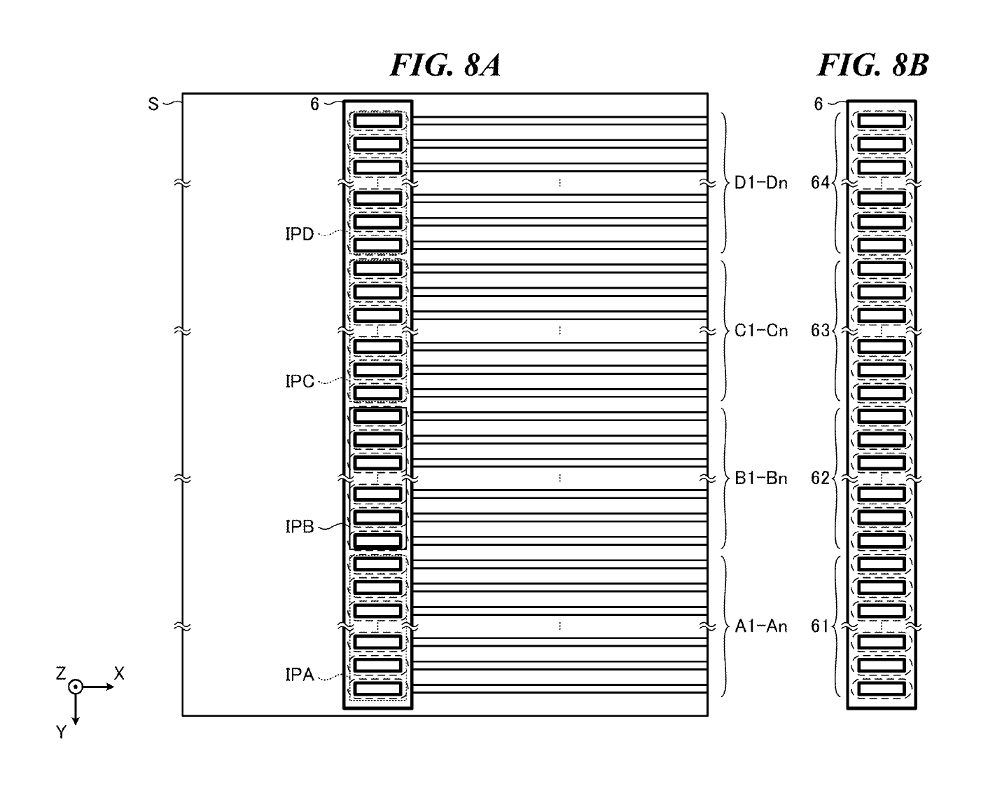

FIG. 8A shows amodification of the mask and the irradiation regions in the fourth embodiment. FIG. 8B shows the modification of the mask in the fourth embodiment. As shown in FIG. 8A, the TFT regions may be arranged in multiple lines on the workpiece S. In addition, an irradiation region irradiated with a single pulse included in the pulse laser beam may extend over two or more lines adjacent to each other. The respective positions of the openings of the mask 6 shown in FIGS. 8A and 8B may not necessarily be shifted from each other in the X direction.

### 7. Laser Irradiation Device Using Galvanometer Mirror (Fifth Embodiment)

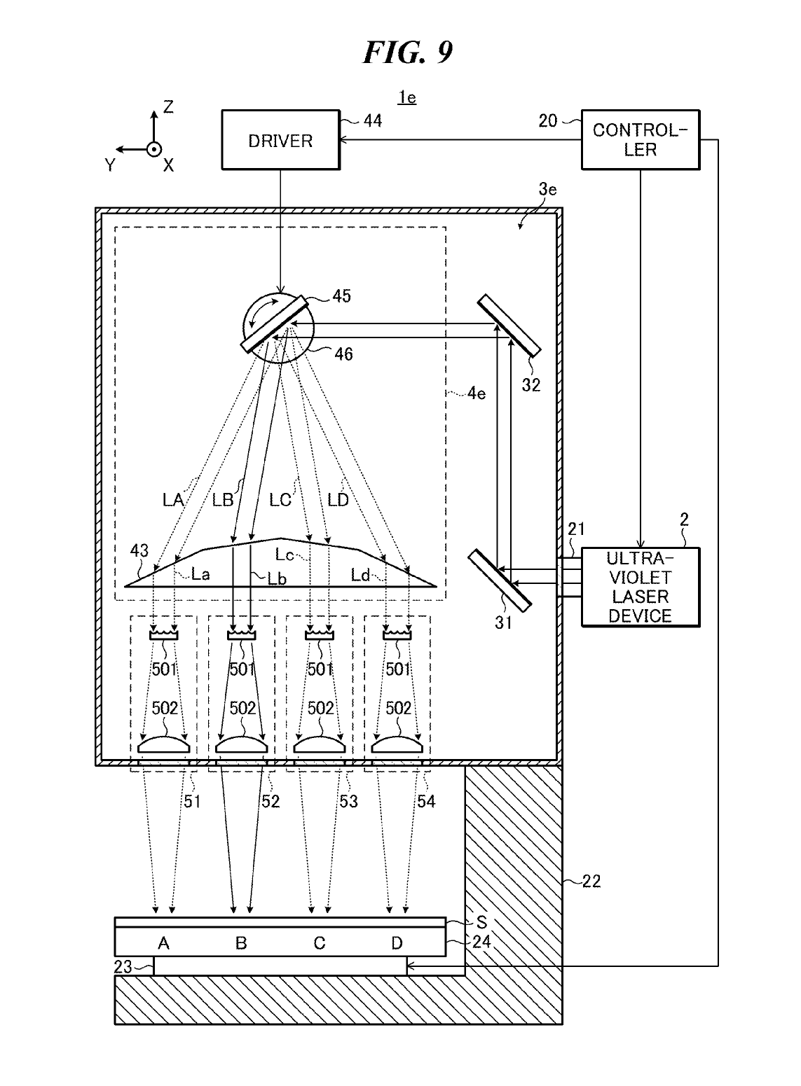

FIG. 9 schematically shows a configuration of a laser irradiation device according to a fifth embodiment of the present disclosure. In a laser irradiation device 1e in the fifth embodiment, beam scan optics 4e may include a galvanometer mirror 45 in place of the polygon mirror. The galvanometer mirror 45 may be connected to a galvanometer motor 46.

The galvanometer mirror 45 may be a planar mirror. The galvanometer motor 46 may be capable of changing inclination angle of the galvanometer mirror 45 at high frequency. The driver 44 may drive the galvanometer motor 46. The controller 20 may control the driver 44. Changing the inclination angle of the galvanometer mirror 45 may result in allocating the pulse laser beam reflected by the galvanometer mirror 45 to the optical paths LA to LD.

Other configurations may be substantially the same as those described with reference to FIGS. 2A to 2D.

In the fifth embodiment, the galvanometer mirror is used in place of the polygon mirror in the laser irradiation device according to the first embodiment; however, the present disclosure is not limited thereto. The galvanometer mirror may be used in place of the polygon mirror in any of the second to fourth embodiments.

### 8. Others

8.1 Ultraviolet Laser Apparatus

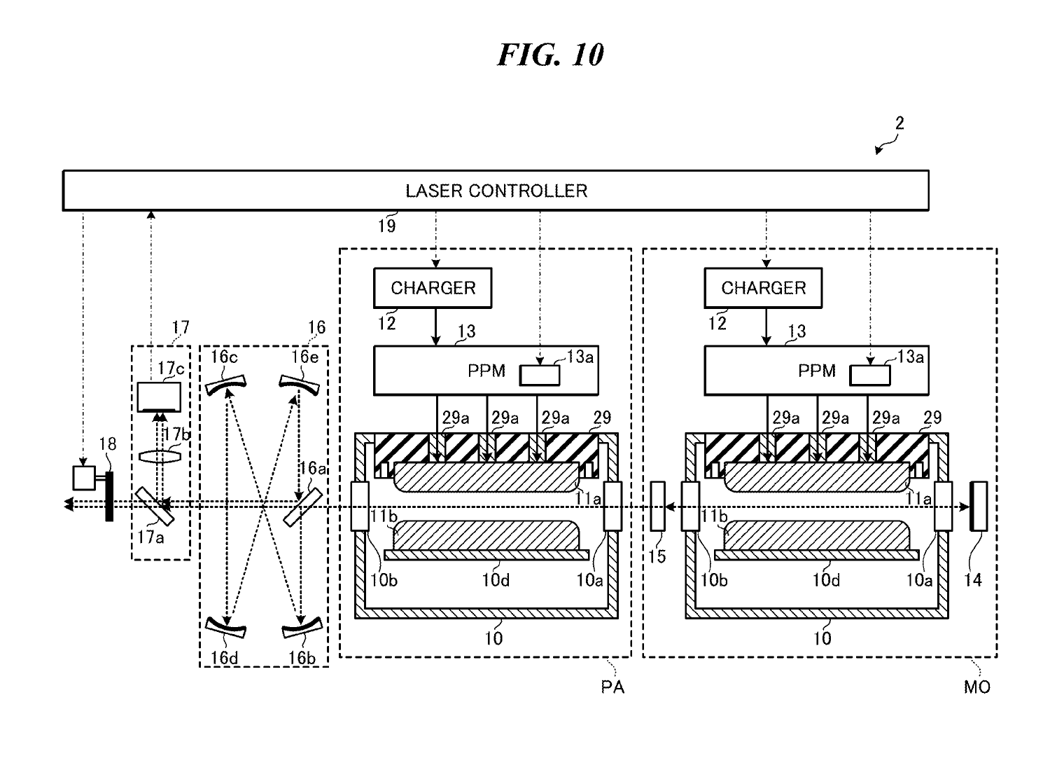

FIG. 10 schematically shows a configuration of the ultraviolet laser device 2 used in each of the above-described embodiments. The ultraviolet laser device 2 may include a master oscillator MO, a power amplifier PA, a pulse stretcher 16, a pulse energy measuring unit 17, a shutter 18, and a laser controller 19.

The master oscillator MO may include a laser chamber 10, a pair of electrodes 11a and 11b, a charger 12, and a pulse power module (PPM) 13. The master oscillator MO may further include a high-reflective mirror 14 and an output coupling mirror 15. FIG. 10 shows an internal configuration of the laser chamber 10 viewed in a direction substantially perpendicular to the traveling direction of the laser beam.

The laser chamber 10 may store a laser gas as the laser medium. The pair of electrodes 11a and 11b may be provided in the laser chamber 10 as electrodes for exciting the laser medium by electric discharge. The laser chamber 10 may have an opening, sealed by an insulating:member 29. The electrode 11a may be supported by the insulating member 29 and the electrode llb may be supported by a return plate 10d. The return plate 10d may be electrically connected to an inner surface of the laser chamber 10 through electric wirings (not shown). In the insulating member 29, conductive members 29a may be molded. The conductive members 29a may apply high-voltage, which is supplied by the pulse power module 13, to the electrode 11a.

The charger 12 may be a direct-current power source for charging a charge capacitor (not shown) of the pulse power module 13 at a predetermined voltage. The pulse power module 13 may include a switch 13a controlled by the laser controller 19. When the switch 13a turns ON, the pulse power module 13 may generate the pulsed high-voltage using electric energy in the charger 12. The high-voltage may be applied to the pair of electrodes 11a and 11b.

The high-voltage applied to the pair of electrodes 11a and 11b may cause dielectric breakdown and cause the electric discharge between the pair of electrodes 11a and 11b. Energy of the electric discharge may excite the laser medium in the laser chamber 10 to a high energy level. When the excited laser medium shifts back to a low energy level, the laser medium, generates light according to the difference of the energy levels.

The laser chamber 10 may have windows 10a and 10b at respective ends of the laser chamber 10. The light generated in the laser chamber 10 may be emitted from the laser chamber 10 through the windows 10a and 10b.

The high-reflective mirror 14 may reflect the light emitted from the window 10a of the laser chamber 10 at high reflectance to return the light to the laser chamber 10.

The output coupling mirror 15 may transmit to output a part of the light emitted from the window 10b of the laser chamber 10 and reflect to return another part of the light to the laser chamber 10.

The high-reflective mirror 14 and the output coupling mirror 15 may thus constitute an optical resonator. The light emitted from the laser chamber 10 may travel back and forth between the high-reflective mirror 14 and the output coupling mirror 15. The light may be amplified at every time passing through a laser gain region between the electrodes 11a and 11b. The amplified light may be emitted through the output coupling mirror 15 as a pulse laser beam.

The power amplifier PA may be provided in the optical path of the pulse laser beam emitted through the output coupling mirror 15 of the master oscillator MO. The power amplifier PA may include, as in the master oscillator MO, a laser chamber 10, a pair of electrodes 11a and 11b, a charger 12, and a pulse power module (PPM) 13. Configurations of these elements may be substantially the same as those in the master oscillator MO. The power amplifier PA may not necessarily include the high-reflective mirror 14 or the output coupling mirror 15. The pulse laser beam, which entered the power amplifier PA through the window 10a, may once pass through the laser gain region between the electrodes 11a and 11b to be emitted through the window 10b.

The pulse stretcher 16 may be provided in the optical path of the pulse laser beam emitted through the window 10b of the power amplifier PA. The pulse stretcher 16 may include a beam splitter 16a, and first to fourth concave mirrors 16b to 16e.

The pulse laser beam emitted from the power amplifier PA may be incident on a first surface of the beam splitter 16a from the right side in FIG. 10. The beam splitter 16a may include a CaF₂ substrate transmitting the pulse laser beam at high transmittance. The CaF₂ substrate may be coated with a high-transmitting film on the first surface and coated with a partially-reflective film on a second surface opposite to the first surface. A part of the pulse laser beam incident on the beam splitter 16a from the right side in FIG. 10 may be transmitted by the beam splitter 16a. Another part of the pulse laser beam may be reflected by the second surface and emitted from the beam splitter 16a through the first surface.

The first to fourth concave mirrors 16b to 16e may sequentially reflect the pulse laser beam reflected by the beam splitter 16a. The pulse laser beam reflected by the first to fourth concave mirrors 16b to 16e may be incident on the second surface of the beam splitter 16a from the upper side in FIG. 10. The first to fourth concave mirrors 16b to 16e may be arranged such that the pulse laser beam incident on the beam splitter 169a from the right side in. FIG. 10 and reflected by the beam splitter 16a may be transferred to the second surface of the beam splitter 16a by the first to fourth concave mirrors 16b to 16e at a magnification ratio of 1:1. The beam splitter 16a may reflect at least a part of the pulse laser beam incident thereon from the upper side in FIG. 10. The pulse laser beam incident on the beam splitter 16a from the right side in FIG. 10 and transferred by the beam splitter 16a and the pulse laser beam incident on the beam splitter 16a from the upper side in FIG. 10 and reflected by the beam splitter 16a may thus be combined in substantially the same beam sizes and in substantially the same beam divergences.

The pulse laser beam incident on the beam splitter 16a from the right side in FIG. 10 and transferred by the beam splitter 16a and the pulse laser beam incident on the beam splitter 16a from the upper side in FIG. 10 and reflected by the beam splitter 16a may have a time difference according to an optical path length of the detour path formed by the first to fourth concave mirrors 16b to 16e. The pulse stretcher 16 may thus stretch the pulse width of the pulse laser beam.

The pulse energy measuring unit 17 may be provided in the optical path of the pulse laser beam from the pulse stretcher 16. The pulse energy measuring unit 17 may include a beam splitter 17a, focusing optics 17b, and an optical sensor 17c.

The beam splitter 17a may transmit a part of the pulse laser beam from the pulse stretcher 16 at high transmittance to the shutter 18. The beam splitter 17a may reflect another part of the pulse laser beam to the focusing optics 17b. The focusing optics 17b may concentrate the light reflected by the beam splitter 17a on a light-receiving surface of the optical sensor 17c. The optical sensor 17c may detect pulse energy of the pulse laser beam concentrated on the light-receiving surface and output data on the pulse energy to the laser controller 19.

The laser controller 19 may send and receive various signals to and from the controller 20. For example, the laser controller 19 may receive the laser emission trigger from the controller 20. Further, the laser controller 19 may send a setting signal to set the charging voltage to the charger 12 and send an instruction signal for ON/OFF of the switch to the pulse power module 13.

The laser controller 19 may receive the data on the pulse energy from the pulse energy measuring unit 17 and control the charging voltage of the charger 12 according to the data on the pulse energy. Controlling the charging voltage of the charger 12 may result in controlling the pulse energy of the laser beam.

Further, the laser controller 19 may correct timing of the instruction signal based on the charging voltage such that the discharge occurs at a predetermined timing from the laser emission trigger.

The shutter 18 may be provided in the optical path of the pulse laser beam transmitted by the beam splitter 17a of the pulse energy measuring unit 17. The laser controller 19 may control the shutter 18 to be closed, from starting laser oscillation, until difference between the pulse energy received from the pulse energy measuring unit 17 and the target pulse energy falls within an acceptable range. The laser controller 19 may control the shutter 18 to be opened if the difference between the pulse energy received from the pulse energy measuring unit 17 and the target pulse energy falls within the acceptable range. Signals to indicate the pulse energy may be sent to the controller 20 to show the timing of the pulse laser beam.

FIG. 10 shows an example where the laser device includes the power amplifier PA and the pulse stretcher 16; however, the power amplifier PA or the pulse stretcher 16 may be omitted.

Further, the laser device does not have to be limited to the excimer laser device. The laser device may be a solid laser device. For example, the solid laser device may be a YAG laser device to generate a third harmonic light having a wavelength of 355 nm or a fourth harmonic light having a wavelength of 266 nm.

8.2 Fly-Eye Lens

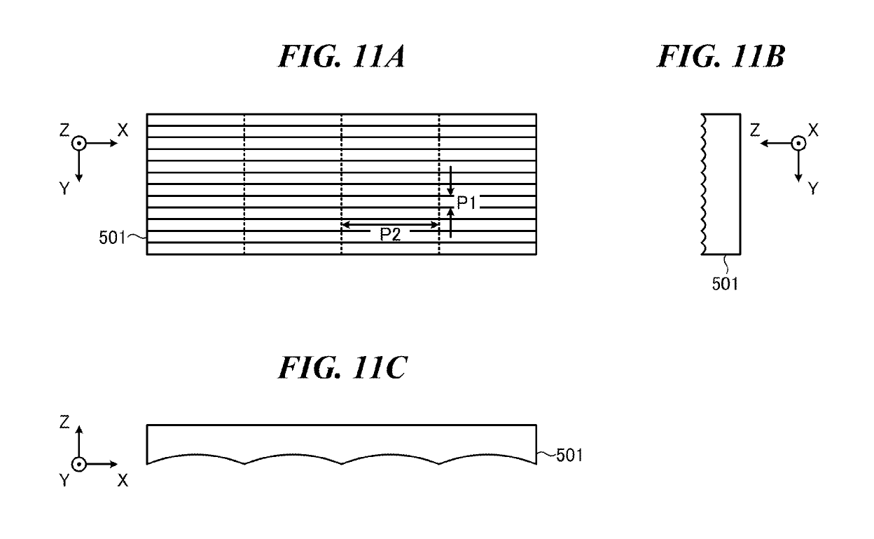

FIGS. 11A to 11C schematically show a configuration of a fly-eye lens 501 used in each of the above-described embodiments as viewed in three directions. The fly-eye lens 501 may be made of a material to transmit the pulse laser beam at high transmittance. In the following description, a surface of the fly-eye lens 501 facing the Z direction is referred to as “front surface” and another surface of the fly-eye lens 501 facing the −Z direction is referred to as “rear surface”.

The front surface of the fly-eye lens 501 may include multiple concave cylindrical surfaces arranged in the I direction at a predetermined pitch P1. The rear surface of the fly-eye lens 501 may include multiple concave cylindrical surfaces arranged in the X direction at a predetermined pitch P2. It is preferable that P2 is larger than P1. A front-side focal plane of the cylindrical surfaces in the front surface of the fly-eye lens 501 and a front-side focal plane of the cylindrical surfaces in the rear surface of the fly-eye lens 501 may coincide with each other

The fly-eye lens 501 and the above-described condenser optics 502 may constitute Koehler illumination. A beam shape of the pulse laser beam at a rear-side focal plane of the condenser optics 502 may be a similar figure to a lens shape of each lens having the dimension represented by P1 and P2 in the fly-eye lens 501. Changing dimension ratio of P1 to P2 may result in adjusting the beam shape of the pulse laser beam to a rectangular shape or a square shape.

The fly-eye lens may include multiple convex lenses in place of the multiple concave lenses. Alternatively, a Fresnel lens may replace the fly-eye lens.

8.3 Configuration of Controller

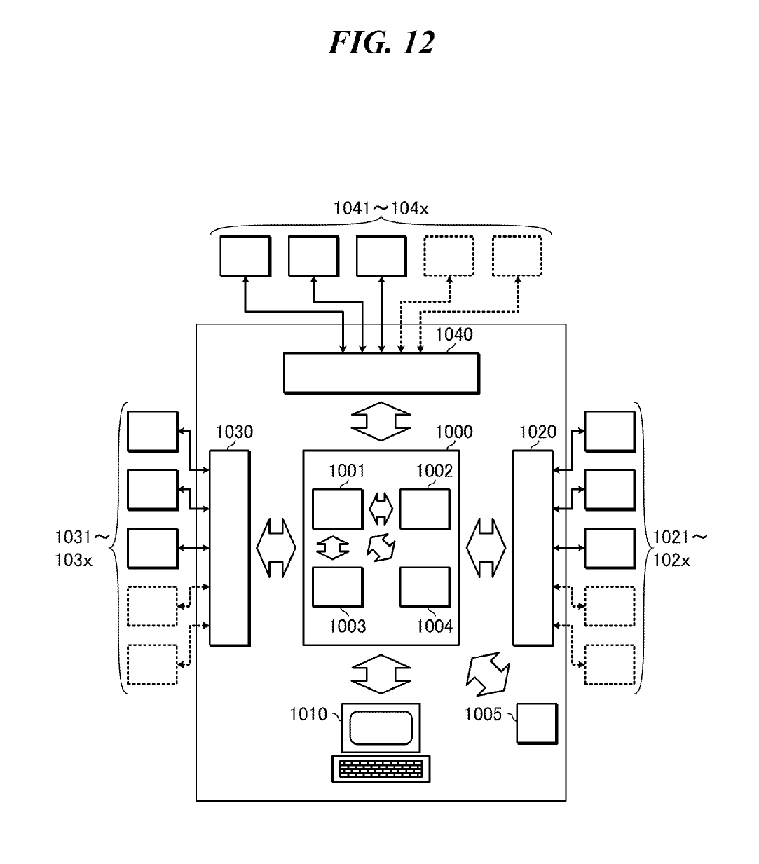

FIG. 12 is a block diagram schematically illustrating a configuration of the controller.

A controller, such as the controller 20, in the above-mentioned embodiments may be constituted by a general-purpose control device, such as a computer or a programmable controller. For example, the controller may be constituted as described below.

### (Configuration)

The controller may include a processor 1000 and other elements connected to the processor 1000. Such elements may include a storage memory 1005, a user interface 1010, a parallel input/output (I/O) controller 1020, a serial I/O controller 1030, and an analog-to-digital (A/D) and digital-to-analog (D/A) converter 1040. The processor 1000 may include a central processing unit (CPU) 1001 and other elements connected to the CPU 1001 including a memory 1002, a timer 1003, and a graphics processing unit (GPU) 1004.

### (Operation)

The processor 1000 may read out programs stored in the storage memory 1005. The processor 1000 may execute the read-out programs, read out data from the storage memory 1005 in accordance with the execution of the programs, or store data in the storage memory 1005.

The parallel I/O controller 1020 may be connected to devices 1021 to 102x communicable through parallel I/O ports. The parallel I/O controller 1020 may control communication using digital signals through the parallel I/O ports that is performed in the process where the processor 1000 executes programs.

The serial I/O controller 1030 may be connected to devices 1031 to 103x communicable through serial I/O ports. The serial I/O controller 1030 may control communication using digital signals through the serial I/O ports that is performed in the process where the processor 1000 executes programs.

The A/D and D/A converter 1040 may be connected to devices 1041 to 104x communicable through analog ports. The A/D and D/A converter 1040 may control communication using analog signals through the analog ports that is performed in the process where the processor 1000 executes programs.

The user interface 1010 may be configured to display progress of executing programs by the processor 1000 to an operator or to receive instructions by the operator to the processor 1000 to stop execution of the programs or to execute interruption processing.

The CPU 1001 of the processor 1000 may perform arithmetic processing of programs. In the process where the CPU 1001 executes programs, the memory 1002 may temporally store programs or temporally store data in the arithmetic process. The timer 1003 may measure time or elapsed time. The timer 1003 may output the time or the elapsed time to the CPU 1001 in accordance with the execution of the programs. When image data is inputted to the processor 1000, the GPU 1004 may process the image data in accordance with the execution of the programs and output the results to the CPU 1001.

The devices 1021 to 102x communicable through the parallel I/O ports, which are connected to the parallel I/O controller 1020, may be the ultraviolet laser device 2, another controller, or the like, and may be used for sending or receiving the laser emission trigger or the signal indicating the timing.

The devices 1031 to 103x communicable through the serial I/O ports, which are connected to the serial I/O controller 1030, may be the ultraviolet laser device 2, the XYZ stage 23, the driver 44, another controller, or the like, and may be used for sending or receiving data.

The devices 1041 to 104x communicable through the analog ports, which are connected to the A/D and D/A converter 1040, may be various sensors, such as the pulse energy measuring unit 17, or the like.

With the above-mentioned configuration, the controller may be capable of achieving the operation illustrated in each of the embodiments.

The aforementioned descriptions are intended to be taken only as examples, and are not to be seen as limiting in any way. Accordingly, it will be clear to those skilled in the art that variations on the embodiments of the present disclosure may be made without departing from the scope of the appended claims.

The terms used in the present specification and in the entirety of the scope of the appended claims are to be interpreted as not being limiting. For example, wording such as “includes” or “is included” should be interpreted as. not being limited to the item that is described as being included. Furthermore, “has” should be interpreted as not being limited to the item that is described as being had. Furthermore, the modifier “a” or “an” as used in the present specification and the scope of the appended claims should be interpreted as meaning “at least one” or “one or more”.

1. A laser irradiation device, comprising:
a laser device configured to emit a pulse laser beam;
beam scan optics configured to allocate the pulse laser beam emitted from the laser device to optical paths;
beam homogenizers provided in the respective optical paths, each of the beam homogenizers being configured to homogenize distribution of light intensity of the pulse laser beam allocated to a corresponding optical path of the optical paths; and
a controller configured to control the beam scan optics to allocate, for each pulse, the pulse laser beam emitted from the laser device to the corresponding optical path of the optical paths.

2. The laser irradiation device according to claim 1, further comprising a mask having openings, each of the openings being provided in the corresponding optical path of the pulse laser beam homogenized by a corresponding beam homogenizer of the beam homogenizers.

3. The laser irradiation device according to claim 2, further comprising transfer optics configured to transfer images of the respective openings to respective predetermined positions.

4. The laser irradiation device according to claim 2, further comprising a stage configured to move a workpiece in a first direction, the workpiece being irradiated with the pulse laser beam homogenized by each of the beam homogenizers, and the first direction being along an irradiation surface of the workpiece, wherein
the beam scan optics is configured to allocate the pulse laser beam to change, in a second direction, irradiation regions irradiated with the pulse laser beam on the irradiation surface, the second direction intersecting with the first direction and being along the irradiation surface.

5. The laser irradiation device according to claim 4, wherein a cross-section of the pulse laser beam, perpendicular to an optical path axis of the pulse laser beam homogenized by each of the beam homogenizers has a shape longer in the first direction than in the second direction.

6. The laser irradiation device according to claim 4, wherein the openings are provided at respective positions that are shifted by regular intervals from one another in the first direction and shifted by regular intervals from one another in the second direction.

7. The laser irradiation device according to claim 4, wherein
the optical paths include a first optical path and a second optical path,
the beam homogenizers include a first beam homogenizer provided in the first optical path and a second beam homogenizer provided in the second optical path,
the openings include a plurality of first openings and a plurality of second openings, the first openings being positioned in an optical path of the pulse laser beam that is homogenized by the first beam homogenizer, the second openings being positioned in an optical path of the pulse laser beam that is homogenized by the second beam homogenizer, and
the first openings and the second openings are provided at positions that are shifted by an interval from one another in the first direction and shifted by an interval from one another in the second direction.

8. A laser irradiation method, comprising:
generating a pulse laser beam;
moving a stage in a first direction; and
changing an optical path of the pulse laser beam to cause the pulse laser beam to enter beam homogenizers in turn, the beam homogenizers being arranged in a second direction.
